(19) United States
(12) Patent Application Publication
(10) Pub. No.: US 2026/0198240 A1
(43) Pub. Date: Jul. 9, 2026

(54) SIDEWALL DOPING METHOD FOR 3D MEMORY DEVICE

(71) Applicant: CHENGDU PBM TECHNOLOGY LTD., Chengdu (CN)

(72) Inventors: Ke WANG, Chengdu (CN); Zezhong PENG, Chengdu (CN)

(21) Appl. No.: 19/556,808

(22) Filed: Mar. 4, 2026

Related U.S. Application Data
(63) Continuation of application No. PCT/CN2025/090638, filed on Apr. 23, 2025.

(30) Foreign Application Priority Data
Aug. 1, 2024 (CN) 202411049133.8

(51) Int. Cl. H10P 32/30; H10P 14/60; H10P 32/20; H10P 34/00; H10P 50/28; H10P 70/00

(52) U.S. Cl. CPC H10P 32/302; H10P 14/6339; H10P 14/6342; H10P 14/668; H10P 32/20; H10P 34/00; H10P 50/283; H10P 70/23; H10P 70/27

(57) ABSTRACT

Provided is a sidewall doping method for a 3D (three dimensional) memory device, which belongs to the technical field of memory device manufacturing. The sidewall doping method for the 3D memory device mainly includes: conducting deposition treatment on a sidewall of the 3D memory device; conducting annealing treatment by either a long-wavelength radiation annealing process or a rapid thermal annealing process; and removing a capping layer portion by using an anisotropic SiO₂ selective and specific vertical etching process; where the above deposition, annealing and etching steps are repeated for a predetermined number of cycles to complete sidewall doping.

### CROSS REFERENCE TO RELATED APPLICATION

This application is a continuation application of International Patent Application No. PCT/CN2025/090638, filed Apr. 23, 2025, which claims the benefit of and priority to Chinese Patent Application No. 202411049133.8, filed Aug. 1, 2024, each of which is hereby incorporated by reference herein in its entirety.

### TECHNICAL FIELD

The present disclosure relates to the technical field of memory device manufacturing, and in particular to a sidewall doping method for a 3D (three-dimensional) memory device.

### BACKGROUND

3D memory devices often require the doping of deep sub-micron and nano-scale thicknesses for sidewalls of deep trenches thereof to form a buffer region that either has a conductive type opposite to that of the heavily-doped, low-resistance semiconductor in the sidewall (e.g., n+ polysilicon), or has the same conductive type but a lower concentration, to optimize device performance. However, conventional ion implantation process cannot be employed for dopant incorporation into sidewalls of 3D devices. Furthermore, conventional vapor-phase diffusion would require extremely high temperatures and long process time, while also failing to ensure the controllability and accuracy of nanoscale diffusion depths in sidewalls with micron-scale depths.

Chinese Patent Application Publication CN101615656A discloses a technical solution involving the use of an isotropic etching method to selectively etch the sidewall of a pre-fabricated, low-resistance semiconductor (heavily doped silicon) followed by the deposition of a buffer layer. However, this technical solution would leave the etched sidewall surface with damage and defects, adversely affecting the contact between the low-resistance semiconductor and the buffer layer. Furthermore, the consistency of etching is not easy to control.

Therefore, a new process capable of precisely controlling sidewall diffusion is required to solve the aforementioned problems.

### SUMMARY

### Technical Problem

In view of the above problems, an object of the present disclosure is to provide a sidewall doping method for a 3D memory device, which enables the doping with deep sub-micron and nano-scale thicknesses in sidewalls of deep trenches in a 3D memory device, allowing for the formation of a buffer layer with precisely controlled depth and concentration.

### Technical Solutions

It has been found that the above object of the present disclosure is achieved using a technical solution, i.e., a sidewall doping method for a 3D memory device, which includes the following steps:
(1) conducting deposition treatment on a sidewall of the 3D memory device by
(1.1) firstly pre-treating a surface of the sidewall using a wet treatment process or a dry treatment process to form adhesion points for subsequent deposition;
(1.2) secondly depositing uniformly an organic precursor containing an element to be doped on a resulting pre-treated sidewall surface by conducting self-aligned monolayer deposition through wet deposition or dry deposition, where
the doping concentration of a single cycle can be optimally adjusted by the dopant-containing organic precursor molecules during the monolayer deposition process. Generally, a longer branch chain length or a larger volume of organic molecules results in a lower initial dopant concentration on silicon sidewall surface due to the self-limitation of the deposition process, and the initial dopant concentration is generally around 10²⁰ cm⁻³ or larger;
(1.3) then depositing or filling with a silicon dioxide capping layer material using a chemical vapor deposition (CVD) or atomic layer deposition (ALD) technique, where
the capping layer material (SiO₂ or other insulating mediums) can effectively prevent the escape of the dopant-containing organic molecules from the silicon surface during annealing, thereby providing a stable dopant diffusion source and ensuring diffusion of dopant(s) into the sidewalls;
(2) conducting annealing treatment by either a long-wavelength radiation annealing process or a rapid thermal annealing process, where
the thickness of the doped region (around 5-20 nm) is determined by the process method and process parameters of the annealing process; and generally, a long-wavelength radiation annealing process, such as microwave annealing, results in a lower thickness of the doped region, and a thermal annealing process, such as rapid thermal annealing, results in a larger thickness of the doped region; and
(3) removing a capping layer portion by using an anisotropic SiO₂ selective and specific vertical etching process; where
steps (1), (2), and (3) are repeated for a predetermined number of cycles to complete sidewall doping.

In some embodiments, in step (1.1), the wet treatment process specifically includes exposing the sidewall to a hydrofluoric acid (HF) solution with a concentration of 1-5 wt % for 1-2 minutes.

In some embodiments, in step (1.1), the dry treatment process specifically includes exposing the sidewall to a H₂ plasma cleaning chamber.

In some embodiments, in step (1.2), the wet deposition specifically includes: immersing a substrate in a precursor-containing solution at a temperature of 100-200° C. for complete reaction.

In some embodiments, in step (1.2), the dry deposition specifically includes: introducing a precursor molecule gas into an atomic layer deposition (ALD) reaction chamber and reacting reactive molecules with a pre-treated sidewall.

In some embodiments, in step (1.2), the organic precursor containing the element to be doped is vinylboronic acid dibutyl ester, or allylboronic acid pinacol ester, or diethyl vinylphosphonate, where vinylboronic acid dibutyl ester and allylboronic acid pinacol ester are boron-containing precursors, which are used to realize p-type doping; and diethyl vinylphosphonate is a phosphorus-containing precursor, which is used to realize n-type doping.

In some embodiments, in step (2), the long-wavelength radiation annealing process is carried out with a substrate temperature of 300-600° C., a light source frequency of 2-10 GHz, and a power of 2000-9000 watts.

In some embodiments, in step (2), the rapid thermal annealing process is carried out at a temperature of 1000° C.

In some embodiments, in step (3), mask definition is conducted before etching to protect an original sidewall surface part.

In some embodiments, in step (3), an anisotropic SiO₂ selective vertical etching process is specifically deep reactive ion etching (DRIE), with CF₄ and O₂ being used as chemical gases for SiO₂ selective and specific vertical etching, a gas flow rate being 10-50 sccm, a radio frequency (RF) power for plasma generation being 100-500 W, a bias power for controlling etch vertical characteristics being 20-200 W, a gas pressure being 10-50 mTorr, and a temperature being −100-25° C.

### Beneficial Effects

The beneficial effects of some embodiments of the present disclosure are as follows:

The method of the present disclosure is applied by using a sidewall containing different materials of silicon and SiO₂ as a substrate, and repeating the three steps of deposition, annealing, and etching the capping layer to complete the doping of deep sub-micron and nano-scale thicknesses in sidewalls of deep trenches in a 3D memory device, which enables the formation of a buffer layer with precisely controlled depth and concentration. Therefore, the method of the present disclosure solves the problem of difficulty in formation of sidewall buffer layer in such 3D devices.

In addition, in the present disclosure, all etching processes are halted at a buffer layer surface. Since the buffer layer is inherently a high-resistance semiconductor region, which is not significantly affected by etching, the precise control in the uniformity of the buffer layer width is achieved, and the diffusion concentration or the buffer layer thickness is precisely controlled by controlling the number of cycles.

### BRIEF DESCRIPTION OF THE DRAWINGS

FIG. 1 shows schematic diagrams of the deposition step in Example 1 of the present disclosure.

FIG. 2 shows schematic diagrams of the annealing step in Example 1 of the present disclosure.

FIG. 3 shows schematic diagrams of the etching step in Example 1 of the present disclosure.

FIG. 4 shows schematic diagrams after repeating the deposition, annealing, and etching steps in Example 1 of the present disclosure for N cycles.

FIG. 5 shows schematic diagrams of the deposition step in Example 2 of the present disclosure.

FIG. 6 shows schematic diagrams of the annealing step in Example 2 of the present disclosure.

FIG. 7 shows schematic diagrams of the etching step in Example 2 of the present disclosure.

FIG. 8 shows schematic diagrams after repeating the deposition, annealing, and etching steps in Example 2 of the present disclosure for N cycles.

### OPTIMUM EMBODIMENT OF THE PRESENT DISCLOSURE

### Example 1

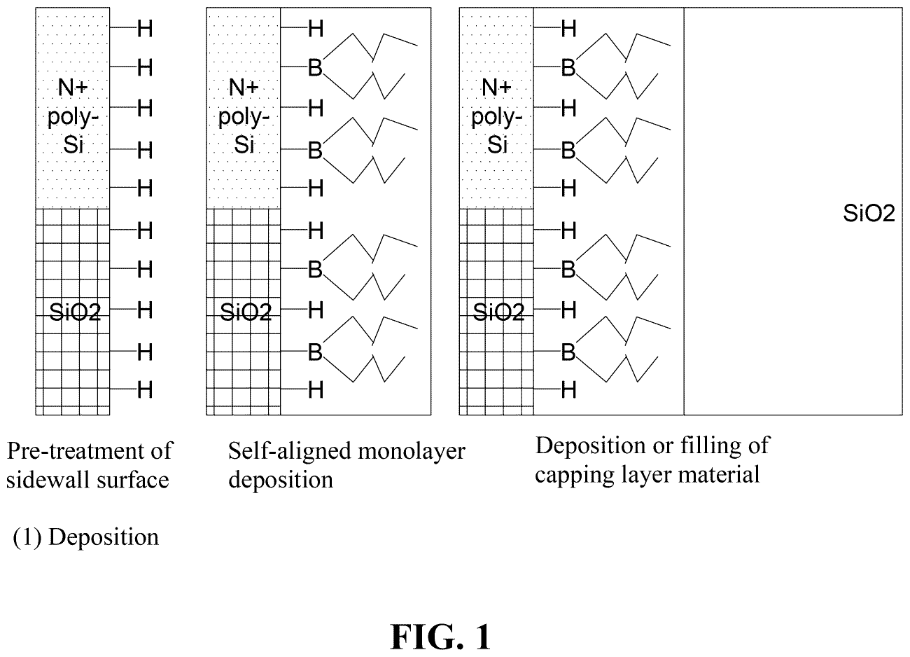

The basic structure of a 3D memory is typically formed by alternately stacking heavily doped n-type polysilicon and silicon dioxide, such that the sidewall thereof presents a repeating pattern of the heavily doped n-type polysilicon and silicon dioxide. For simplicity, the sidewall in FIG. 1 shows only one layer of heavily doped n-type polysilicon denoted as N+ poly-Si and one layer of silicon dioxide denoted as SiO₂.

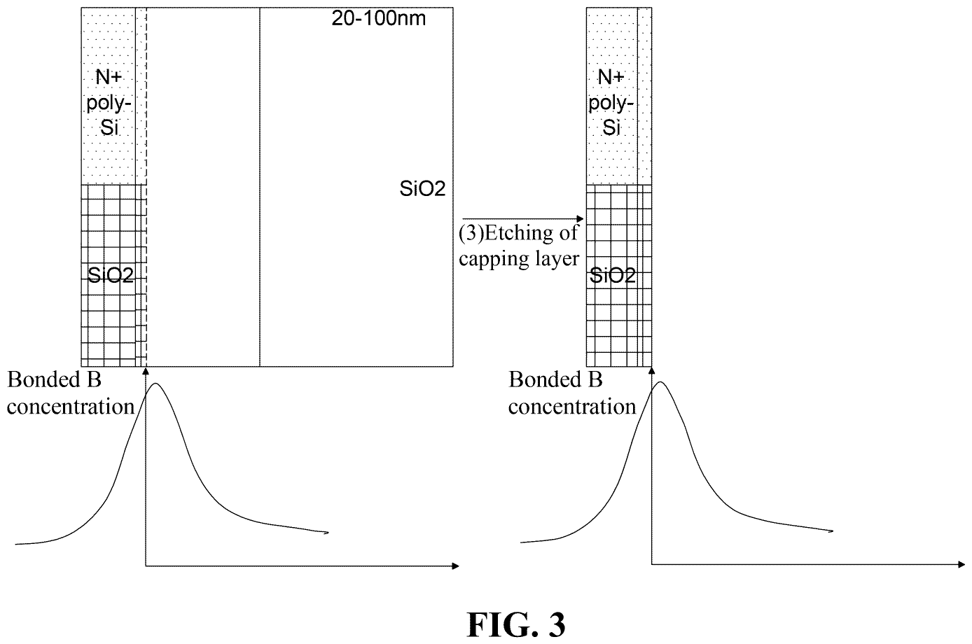

FIG. 1 to FIG. 4 show a first specific embodiment of the sidewall doping method for a 3D memory device according to the present disclosure, including/consisting of the following steps:
(1) Deposition treatment was conducted on a sidewall of a 3D memory device, which was performed by specific steps as follows:
(1.1) Firstly, the surface of the sidewall was pre-treated using a wet treatment process, i.e., exposing the sidewall to a hydrofluoric acid (HF) solution with a concentration of 1-5 wt % for 1-2 minutes, to form adhesion points for subsequent deposition.
(1.2) Secondly, self-aligned monolayer deposition was conducted by wet deposition, i.e., immersing a substrate in a precursor-containing solution at a temperature of 100-200° C. for complete reaction, so as to deposit a boron-containing organic precursor uniformly on the pre-treated sidewall surface, where the organic precursor was vinylboronic acid dibutyl ester. Polylines in FIG. 1 represent organic branch chain moieties of the organic precursor molecule. This process was self-aligned and self-limited, which was a self-limited chemical reaction.
(1.3) A silicon dioxide capping layer material was deposited using a chemical vapor deposition (CVD) technique, where the presence of the capping layer can effectively help the boron dopant to form as bonded dopant in the subsequent annealing process, leading to effective doping; and
the thickness of the capping layer depended on the predefined vertical bit-line width of the 3D memory array, and the thickness of the deposited monolayer depended on the molecular structure of the deposited precursor.
(2) Annealing treatment was conducted using a long-wavelength radiation annealing process, with a substrate temperature of 300-600° C., a light source frequency of 2-10 GHz, and a power of 2000-9000 watts.

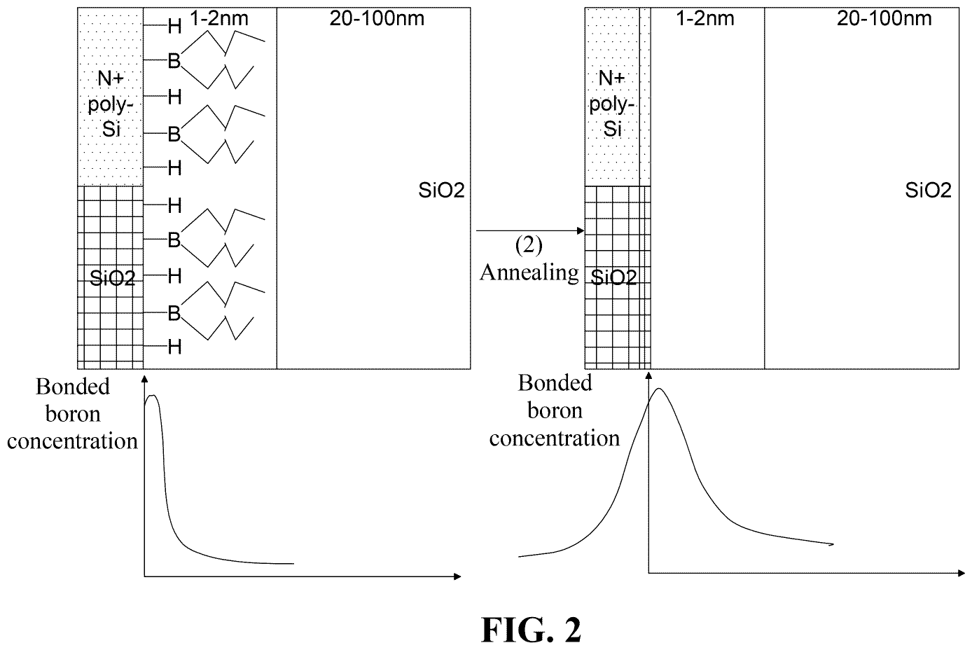

The concentration of bonded-state boron before annealing was concentrated on a surface of an original sidewall, and the concentration of bonded-state boron after annealing was diffused into the original sidewall and the capping layer to a certain range. Due to the diffusion of boron atoms, the organic molecule moieties that have lost their boron atom lost the connection with the original sidewall surface and subsequently diffused randomly into the capping layer. FIG. 2 illustrates changes of bonded-state boron concentration after annealing.
(3) In this example, mask definition was performed before etching to protect the original sidewall surface part, and then the capping layer portion was removed using an anisotropic SiO₂ selective and specific vertical etching process.

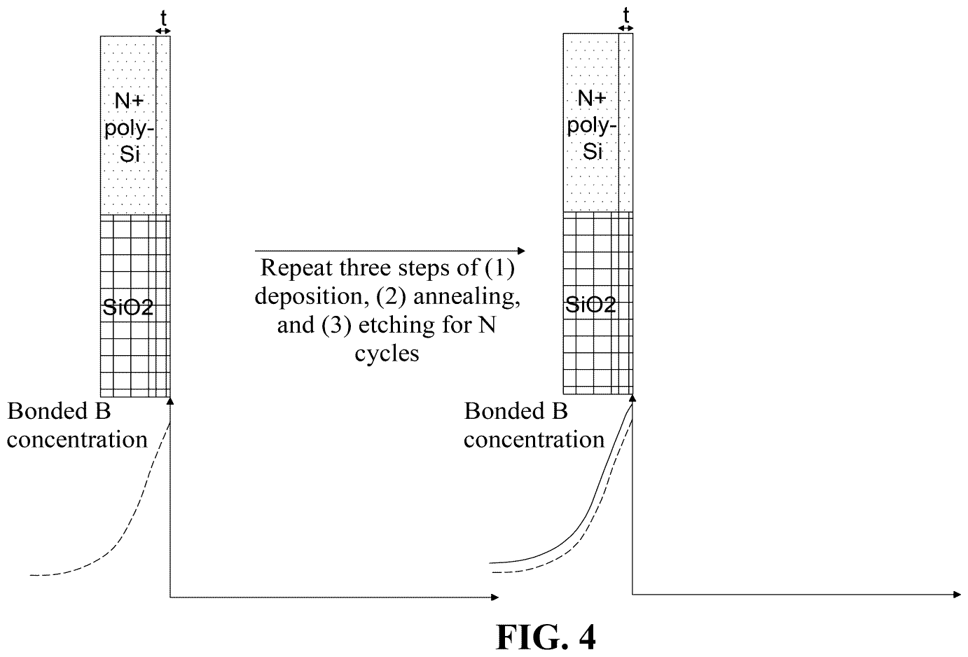

The three steps of (1) deposition, (2) annealing, and (3) etching were repeated for N cycles to complete the doping of the sidewall. FIG. 4 shows that after N cycles, the concentration in the doped region was increased by N times, and the thickness t remained relatively constant, at about 5-20 nm.

The doped region formed by a single cycle was called a buffer layer after multiple cycles.

Determination of the number of cycles N: In the case where the doping type of the buffer layer was opposite to the conductive type of a low-resistance semiconductor layer in the original sidewall, for instance, to form a 20 nm p-type buffer layer on the original n+ silicon sidewall (with the n⁺-p junction depth typically defined as the depth where the P-type dopant concentration reaches 10¹⁸ cm⁻³), the method of Example 1 may be used. If a single cycle yields a concentration of about 10¹⁷ cm⁻³ at a depth of 20 nm, repeating the cycle 10 times could achieve the required concentration.

### Embodiments of the Present Disclosure

### Example 2

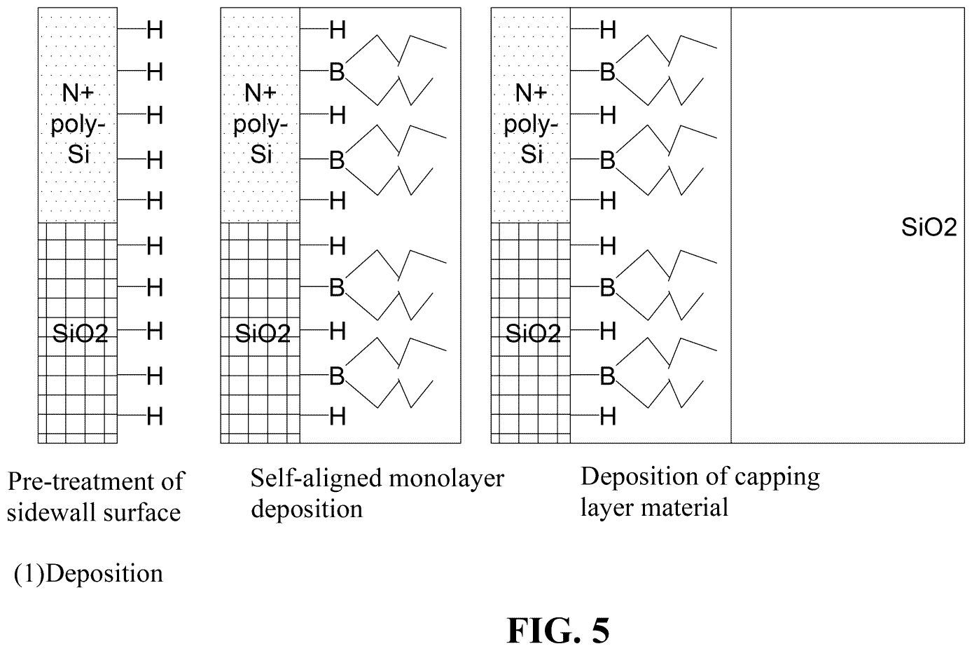

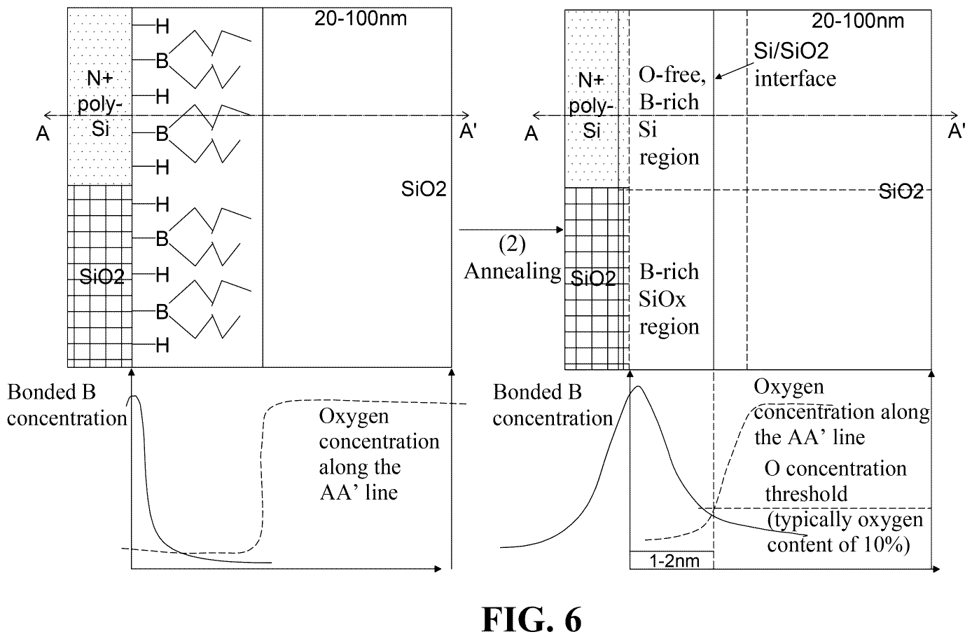

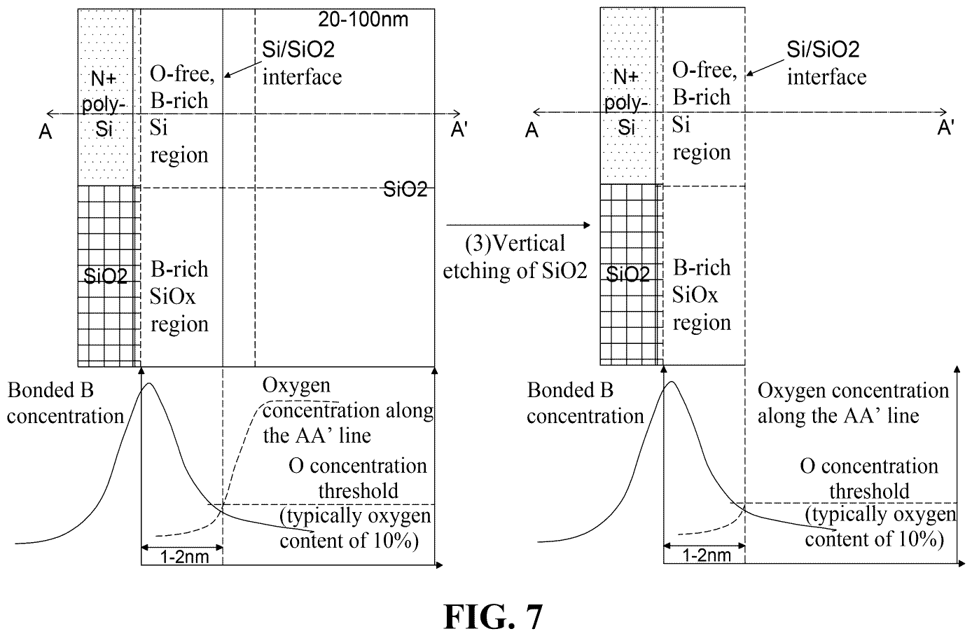

Different from Example 1, during partial annealing process, the oxygen atoms in the capping layer SiO₂ diffused to some extent into the silicon sidewall, resulting in a nanoscale shift of the Si/SiO₂ interface (typically 1-2 nm). In this case, as shown in FIG. 5 to FIG. 8, a second specific embodiment of the sidewall doping method for a 3D memory device according to the present disclosure was proposed, including/consisting of the following steps:
(1) Deposition treatment was conducted on a sidewall of a 3D memory device. The specific methods in this step were the same as those in step (1) of Example 1.

The sidewall in FIG. 5 shows only one layer of heavily doped n-type polysilicon denoted as N+ poly-Si and one layer of silicon dioxide denoted as SiO₂.
(2) Annealing treatment was conducted according to those in Example 1, except that: since the content of oxygen concentration in different regions was not constant during the annealing process, the interface between silicon and the silicon oxide capping layer shifted. An oxygen concentration of about 10% was used as a reference for defining the Si/SiO₂ interface, based on the rationale that after isotropic, SiO₂-specific etching (for instance, fully immersing a sample obtained after pretreatment and anneal on a silicon substrate in a HF solution for wet etching) until all SiO₂ was removed, the oxygen concentration at the corresponding position on the resulting new surface was about 10%.
(3) The etching method in this example should be anisotropic vertical etching; otherwise, SiO₂ in the sidewall would been affected. In this example, selective and specific etching, which targets only SiO₂, was also required to achieve etching according to the new Si/SiO₂ interface. In this example, a deep reactive ion etching (DRIE) technique was used, with CF₄ and O₂ being used as chemical gases for SiO₂ selective and specific vertical etching, a gas flow rate being 10-50 sccm, an RF power for plasma generation being 100-500 W, a bias power for controlling etch vertical characteristics being 20-200 W, a gas pressure being 10-50 mTorr, and a temperature being −100-25° C.

In this example, mask definition was not required before etching, and the etch range was defined by the new Si/SiO₂ interface after annealing. This etching process did not proceed to the point where the oxygen content was only 0% and therefore did not reach the original Si/SiO₂ interface, thus creating a new Si/SiO₂ interface. Different SiO₂ specific etching methods resulted in different new Si/SiO₂ interfaces, as well as different oxygen concentrations, so 10% was only a reference value.

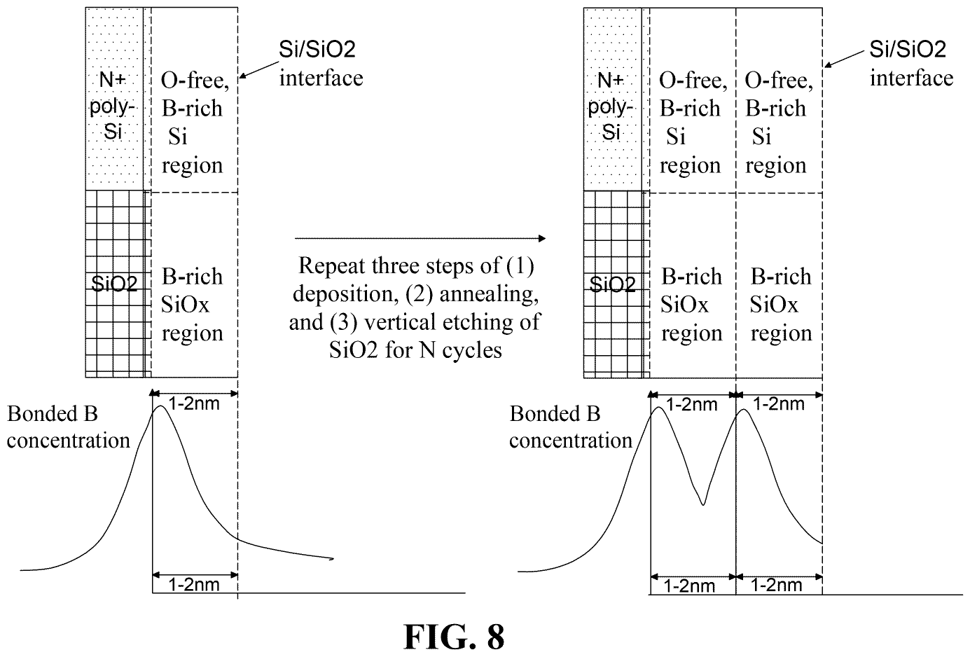

The three steps of (1) deposition, (2) annealing, and (3) etching were repeated for N times to complete the doping of the sidewall. FIG. 8 shows that after repeating for N times, the thickness of the doped region was increased by N times, while the doping concentration profile did not show significant changes.

For the method of Example 2, with each repeated cycle, the thickness of the doped region increased incrementally, while the doping concentration profile was not significantly varied. Thus, this method can be used to achieve precise control of the doped region thickness, i.e., the inward diffusion thickness of the dopant plus the sidewall thickness added over multiple cycles. Since the Si/SiO₂ interface was typically shifted 1-2 nm, which was less than the typical thickness of the inward diffusion of the dopant (for example, in microwave annealing, when 10¹⁸ cm⁻³ was defined as the criterion for the measurement boundary, the thickness was 5 nm), the concentration throughout this doped region could all reach 10¹⁸ cm⁻³ or above.

The doped region formed by a single cycle finally formed a buffer layer after multiple cycles.

Determination of the number of cycles N: if a single cycle resulted in a 2 nm shift of Si/SiO₂ interface and an inward diffusion depth for the first cycle was 5 nm (defined by the P-type dopant concentration of 10¹⁸ cm⁻³), a total of 8 cycles could meet the requirement of forming a 20 nm thick buffer layer.

In summary, in the case where the doping type of the buffer layer was opposite to the conductive type of a low-resistance semiconductor layer in the original sidewall, for instance, to form a 20 nm p-type buffer layer on the original n+ polysilicon sidewall (with the n⁺-p junction depth being typically defined by a P-type dopant concentration of 10¹⁸ cm⁻³), the methods of Example 1 or Example 2 can be selected.

In the case where the doping type of the buffer layer being the same with the conductive type of a low-resistance semiconductor layer in the original sidewall, for instance, to form a 20 nm p-type buffer layer on the original p+ polysilicon sidewall, it is preferred to use the method of Example 2.

The above examples of the present disclosure are merely examples given for the purpose of illustrating the present disclosure and are not intended to limiting the embodiments of the present disclosure. For those of ordinary skill in the art, other variations and changes in different forms may be made on the basis of the above description. It is not possible to list all of the embodiments herein. Any obvious variations and changes derived from the technical solutions of the present disclosure are still within the scope of the present disclosure.

What is claimed is:

1. A sidewall doping method for a 3D memory device, comprising the steps of:
(1) conducting deposition treatment on a sidewall of the 3D memory device by
(1.1) firstly pre-treating a surface of the sidewall using a wet treatment process or a dry treatment process to form adhesion points for subsequent deposition;
(1.2) secondly depositing uniformly an organic precursor containing an element to be doped on a resulting pre-treated sidewall surface by conducting self-aligned monolayer deposition through wet deposition or dry deposition; and
(1.3) then depositing or filling with a silicon dioxide capping layer material using a chemical vapor deposition (CVD) or atomic layer deposition (ALD) technique;
(2) conducting annealing treatment by either a long-wavelength radiation annealing process or a rapid thermal annealing process; and
(3) removing a capping layer portion by using an anisotropic SiO₂ selective and specific vertical etching process; wherein
steps (1), (2), and (3) are repeated for a predetermined number of cycles to complete sidewall doping.

2. The sidewall doping method for the 3D memory device as claimed in claim 1, wherein in step (1.1), the wet treatment process comprises exposing the sidewall to a hydrofluoric acid (HF) solution with a concentration of 1-5 wt % for 1-2 minutes.

3. The sidewall doping method for the 3D memory device as claimed in claim 1, wherein in step (1.1), the dry treatment process comprises exposing the sidewall to a H₂ plasma cleaning chamber.

4. The sidewall doping method for the 3D memory device as claimed in claim 1, wherein in step (1.2), the wet deposition comprises: immersing a substrate in a precursor-containing solution at a temperature of 100-200° C. for reaction.

5. The sidewall doping method for the 3D memory device as claimed in claim 1, wherein in step (1.2), the dry deposition comprises: introducing a precursor molecule gas into an atomic layer deposition (ALD) reaction chamber, and reacting reactive molecules with a pre-treated sidewall.

6. The sidewall doping method for the 3D memory device as claimed in claim 1, wherein in step (1.2), the organic precursor containing the element to be doped is vinylboronic acid dibutyl ester, allylboronic acid pinacol ester, or diethyl vinylphosphonate.

7. The sidewall doping method for the 3D memory device as claimed in claim 1, wherein in step (2), the long-wavelength radiation annealing process is carried out with a substrate temperature of 300-600° C., a light source frequency of 2-10 GHz, and a power of 2000-9000 watts.

8. The sidewall doping method for the 3D memory device as claimed in claim 1, wherein in step (2), the rapid thermal annealing process is carried out at a temperature of 1000° C.

9. The sidewall doping method for the 3D memory device as claimed in claim 1, wherein in step (3), mask definition is conducted before etching to protect an original sidewall surface part.

10. The sidewall doping method for the 3D memory device as claimed in claim 1, wherein in step (3), the anisotropic SiO₂ selective and specific vertical etching process is deep reactive ion etching (DRIE), with CF₄ and O₂ being used as chemical gases for SiO₂ selective and specific vertical etching, a gas flow rate being 10-50 sccm, a radio frequency (RF) power for plasma generation being 100-500 W, a bias power for controlling etch vertical characteristics being 20-200 W, a gas pressure being 10-50 mTorr, and a temperature being −100° C. to 25° C.
